(19) United States
(12) Patent Application Publication
(10) Pub. No.: US 2005/0168941 A1
(43) Pub. Date: Aug. 4, 2005

(54) System and apparatus for heat removal

(76) Inventors: John L. Sokol, Montclair, CA (US); Allen J. Amaro, Fremont, CA (US); Alfred A. Zinn, Palo Alto, CA (US); K.R.S. Murthy, San Jose, CA (US)

Correspondence Address: FISH & RICHARDSON P.C., PO BOX 1022, MINNEAPOLIS, MN, 55440-1022, US

(21) Appl. No.: 10/971,565

(22) Filed: Oct. 22, 2004

Related U.S. Application Data
(60) Provisional application No. 60/514,594, filed on Oct. 22, 2003.

(51) Int. Cl. H05K 7/20

(52) U.S. Cl. 361/688; 361/704

(57) ABSTRACT

A system for removing heat from an encased electronic device. The system includes a thermal ground, conduction pathways including flexible thermal connectors that thermally coupling heat-producing elements to the thermal ground so that the thermal ground receives heat produced by the heat-producing elements, and a heat dissipation element thermally coupled to the thermal ground and configured to transfer heat from the thermal ground to an environment outside the device. The conduction pathways and heat dissipation element provide a capacity to remove heat from the encased electronic device such that heat removal by convection from the heat-producing elements is not required.

This application claims the benefit of U.S. application Ser. No. 10/783,385, filed on Feb. 19, 2004, and U.S. Provisional Application No. 60/514,594, filed on Oct. 22, 2003, each of which is incorporated by reference herein.

### BACKGROUND

This invention relates to heat transfer.

With continuing advances in electronics and especially computer electronics, electronic devices are getter smaller, faster, and hotter. Advances in the manufacture and design of computer chips (CPUs) have, for example, resulted in denser chips and dramatic increases in processing speed, as well as increased production of heat. Advances in the design and use of graphics cards (and other PC cards or boards) have resulted in more detailed simulation graphics that can be shown in real time, as well as increased production of heat. Similarly, advances in hard disk technology have resulted in storage of more data with rapid access, as well as increased production of heat.

Heat jeopardizes the performance and viability of electronic devices. For example, as the temperatures of CPUs rise, failure rates increase dramatically. In an encased electronic device, for example a conventional computer, the heat produced by electronic devices, for example CPUs and PC cards, can readily accumulate and rise to dangerous levels. Such accumulation is exacerbated when there are multiple heat-producing elements, especially if they are clustered near one another, and when the electronic device is small. Under these circumstances—with the production of more heat in a smaller encased space—heat is less readily dissipated away from the heat-producing electronic devices.

To ensure the proper and long-term functioning of encased electronic devices, heat must be removed. Conventional computers remove the heat produced inside an encased computer with fans. The fans can be situated inside the computer, and can circulate air through vents in the computer casing, thus cooling the components inside. In addition, heat sinks can be mounted to electronic components inside an encased electronic device.

### SUMMARY

The invention provides systems and apparatus for removing heat from an encased electronic device.

In general, in one aspect, the system includes a thermal ground, one or more conduction pathways that thermally couple one or more heat-producing elements of an encased electronic device to the thermal ground so that the thermal ground receives heat produced by the heat-producing elements, and a heat dissipation element that is thermally coupled to the thermal ground and configured to transfer heat from the thermal ground to an environment external to the encased electronic device. At least a portion of one of the one or more conduction pathways is a flexible thermal connector.

Particular implementations can include one or more of the following features. The flexible thermal connector can be made of pitch-based carbon fiber, diamond, vapor grown carbon fibers (VGCF), or carbon nanotubes. The flexible thermal connector can include filler material selected from the group consisting of silver, gold, copper, aluminum, graphite, carbon black, emerald, sapphire, beryllium oxide (BeO), boron nitride (BN), silicon carbide (SiC), and aluminum nitride (AlN). The flexible thermal connector can be made of thermally conductive fibers coated with a more highly thermally conductive material. The flexible thermal connector can have a protective layer that provides thermal insulation. The protective layer can be made in whole or in part from polyvinylchloride (PVC), nylon, polyethylene, polypropylene, polyester, polyurethane foam, long density polyethylene (LDPE), closed cell foams, sponge rubber, natural cork, silica aerogel, Cab-O-Sil, mica, wood flour, zirconium dioxide, or silicon dioxide.

The flexible thermal connector can be secured to a thermal ground, a heat spreader, or a heat-producing device with a collar. The flexible thermal connector can be thermally coupled to a thermal ground, a heat spreader, or a heat-producing device with a plating of a highly conductive material or a thermal pad. The flexible thermal connector can be thermally coupled to a heat-producing device and electrically insulated from the heat-producing device. The flexible thermal connector can thermally couple one of the one or more heat-producing elements to the thermal ground so that the thermal ground receives heat produced by the heat-producing elements. The flexible thermal connector can be coupled to one of the one or more heat-producing elements at a first area and is coupled to the thermal ground at a second area, where the first area is smaller than the second area.

The heat dissipation element can be made of fibers that are free-floating and moveable by convection. The electronic device can include a computer or a computer subsystem encased in a thermally conductive casing. The electronic device can include two or more computers or computer subsystems encased in a thermally conductive casing and separated by thermal spreaders. The electronic device can be a portable laptop computer.

In general, in another aspect, an apparatus for dissipating heat includes a bundle of thermally conductive and flexible fibers thermally coupled to a heat-producing device, at least some of the fibers being unsecured at one end and moveable by convection. In general, in another aspect, a system for removing heat includes a thermal ground, one or more conduction pathways that thermally couple one or more heat-producing elements of an encased electronic device to the thermal ground so that the thermal ground receives heat produced by the heat-producing elements, and a heat dissipation element that is thermally coupled to the thermal ground and configured to transfer heat from the thermal ground to an environment external to the encased electronic device. The heat dissipation element is made of fibers that are free-floating and moveable by convection.

Particular implementations can include one or more of the following features. The electronic device can be a computer encased in a thermally conductive casing, and the heat-producing elements of the computer can include any combination of a central processing unit, one or more PC cards, one or more disk drives, and one or more power supplies.

The invention can be implemented to realize one or more of the following advantages, alone or in various possible combinations. Heat can be removed from a computer without the use of fans. Heat can be removed from a computer with little noise or in silence. Heat can be removed without the vibrations, electromagnetic noise, or mechanical resonance caused by fans. The variability of magnetic and electric fields in the computer can be reduced. Maintenance issues created by the use of fans can be reduced or eliminated. Mechanical fatigue of computer components can be reduced. The circulation of air into a computer is not necessary. The computer can be sealed. The computer can exclude moisture, and can be operated in moist or chemically adverse environments. Maintenance issues created by entry into a computer of dust, ions, debris, airborne chemicals, and contaminants can be minimized or eliminated. The computer can be protected from external electric, magnetic and electromagnetic fields. Performance of the computer can be improved. The lifespan and reliability of the computer can be improved. One implementation includes all of the above described advantages. Heat can be dissipated by the use of flexible fibers, which can be folded or otherwise compacted when not in use.

The details of one or more implementations of the invention are set forth in the accompanying drawings and the description below. Other features, objects, and advantages of the invention will be apparent from the description and drawings, and from the claims.

### DESCRIPTION OF DRAWINGS

FIG. 1 is a diagram of a system for removing heat from a computer according to one aspect of the invention.

FIG. 2A illustrates a system for removing heat from a computer according to one aspect of the invention.

FIG. 2B illustrates a system for removing heat from multiple units according to one aspect of the invention.

FIG. 2C illustrates a system for removing heat from a computer or unit using a hairy heat exchanger as a heat dissipation element according to one aspect of the invention.

FIG. 2D illustrates a system for removing heat from a portable device such as a laptop according to one aspect of the invention.

FIG. 3A illustrates components of a system for removing heat from a computer, including a heat dissipation element, thermal ground, thermal connector, and a CPU mounted on a circuit board.

FIG. 3B illustrates components of a system for removing heat from a computer, including a heat dissipation element, thermal ground with thermal spreader, flexible thermal connectors, and a CPU and memory chip mounted on a circuit board.

FIG. 4A shows a thermal connector having two parts but kept under pressure by springs.

FIGS. 4B-D illustrate flexible thermal connectors.

FIGS. 5A-F each illustrates a thermal connector for thermally coupling a PC card to a thermal ground according to one aspect of the invention.

FIG. 5G illustrates a system of thermally conductive vias in a circuit board for the transfer of heat according to one aspect of the invention.

FIGS. 6A-E each illustrates a thermally conductive bridge having two connectable segments according to one aspect of the invention.

FIGS. 6F-G each illustrates a thermally conductive bridge having two connectable segments for use with a flexible thermal connector according to one aspect of the invention.

FIG. 7 illustrates a disk drive covered by a thermally conductive elastomer and coupled to a thermal ground in the shape of a plate by direct contact leaving the connecting ribbons free to connect as needed according to one aspect of the invention.

FIGS. 8A-C each illustrates a disk drive covered by an elastomer according to one aspect of the invention.

FIGS. 9A-B each illustrates a disk drive covered by an elastomer and thermally coupled to a thermal ground according to one aspect of the invention.

FIGS. 10A-B are diagrams indicating the path of heat flow for one aspect of the invention, as used in a mathematical thermal model.

FIG. 11 is a diagram indicating placement of thermal sensors in one implementation of the invention.

FIGS. 12A-D are graphs showing temperature as a function of time at various locations during operation of one implementation of the invention.

FIGS. 13A-B are graphs showing temperature and thermal resistance, respectively, of the heat dissipation element in one implementation of the invention, as a function of the power that is being dissipated with natural convection.

FIGS. 14A-B are graphs showing temperature and thermal resistance, respectively, of the heat dissipation element in one implementation of the invention, as a function of the power that is being dissipated with forced convection.

Like reference symbols in the various drawings indicate like elements.

### DETAILED DESCRIPTION

The invention provides systems and apparatus for removing heat from an encased electronic device.

A heat dissipation element dissipates, to an environment external to a casing of the electronic device, heat that is produced by exothermic or heat-producing elements of the electronic device, for example, a CPU, one or more PC cards, a disk drive, and a power supply. Each of one or more such heat-producing elements is thermally coupled to a thermal ground. The thermal ground can be any shape, for example, a plate, rod, block, sphere, pyramid, or block. In one implementation, the thermal ground can be the casing of the electronic device. In another implementation, the thermal ground includes one or more heat spreaders, which can be any shape and are thermally coupled to the thermal ground. Examples of heat spreaders include a plate and a flexible thermal blanket. The thermal ground receives heat produced by the heat-producing elements and transfers it to the heat dissipation element. In one implementation, the system includes a common thermal ground for all of the heat-producing elements. The heat dissipation element then dissipates the heat into the environment external to the casing. In one implementation, the thermal ground, heat dissipating element, and the main supporting structure for all components are integrated as one element.

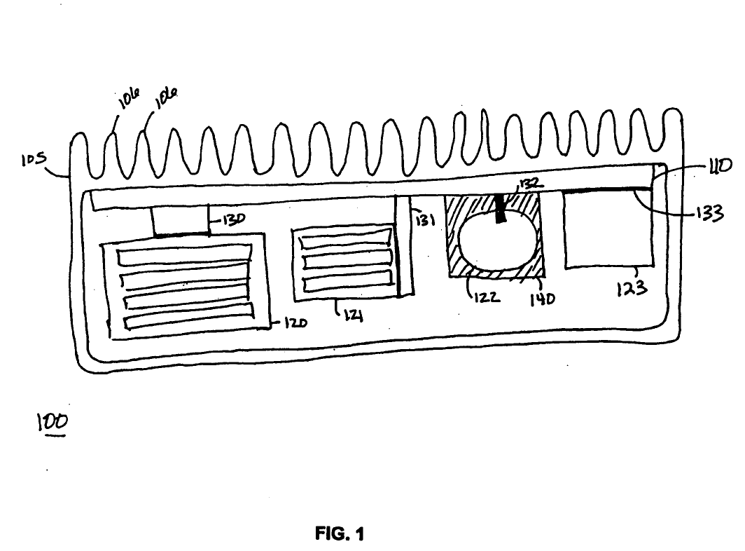

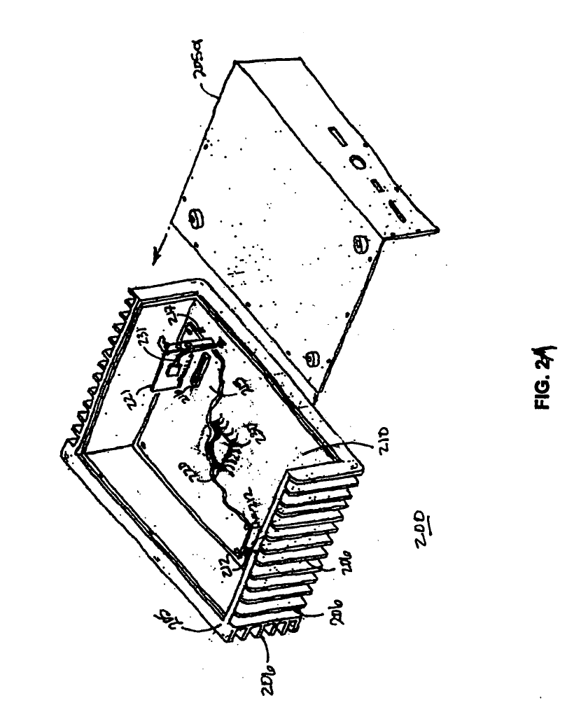

FIG. 1 shows a system in accordance with the invention for removing heat from an encased electronic device, which can be, for example, a computer. The system for removing heat 100 includes one or more conduction pathways, a heat dissipation element 106, and a thermal ground 110. The ground 110 is thermally coupled to the heat dissipation element 106, for example, by direct contact as shown. The ground 110 and the heat dissipation element 106 can be a part of a casing 105, and the ground can be structurally supportive for one or more heat-producing elements. The casing 105 encloses one or more heat-producing elements, for example, a CPU 120 on a circuit board, PC card 121, disk drive 122, and a power supply 123. Each heat-producing element is thermally coupled to the ground 110, forming a conduction pathway. For example, a CPU 120 can be thermally coupled to the ground 110 by a thermal connector 130, a PC card can be thermally coupled to the ground 110 by a detachable thermal connector 131, a disk drive 122 can be thermally coupled to the ground 110 by a thermal connector 132 that pierces an insulator 140 around the disk drive, and a power supply 123 can be thermally coupled to the ground 110 by direct contact 133. The thermal connectors and direct contact (in the case of the power supply) can provide a conduction pathway through which heat can move from the heat-producing elements to the thermal ground.

In the present specification, the term conduction pathway refers to any pathway through which heat can move by conduction. A conduction pathway between a heat-producing element and the thermal ground can be formed, for example, by one or more thermal connectors and/or one or more thermal plugs. A thermal connector can have various size and shape. Examples of thermal connectors include a thermal bridge, a thermally conductive bridge, and a flexible thermal connector. Other examples are provided below.

The thermal ground 110 can receive heat from each of several multiple heat-producing elements 120-123, directly or indirectly, for example, through one or more thermal connectors and/or heat spreaders. The thermal ground 110 is made of a thermally conductive material, for example, copper or aluminum. Other thermally conductive materials can be used. The ground can be fabricated from plate, rod, or block form materials and can be a ceramic, metal, polymer composite of several different materials, including anisotropic graphite fiber composites, carbon fiber composites, nano-tube graphite, and carbon nano-tubes. The thermal ground can be a flexible blanket made in part of thermally conductive materials, for example, anisotropic graphite fiber composites, carbon fiber composites, nano-tube graphite, and carbon nanotubes.

The ground 110 may serve as a supportive structure for all elements of the encased electronic device, and can have a large face relative to the size of the heat-producing elements or multiple surfaces so that it can be coupled to and accumulate heat from several heat-producing elements. In one implementation, the thermal ground is the main structure for mounting all electronic components of the encased electronic device. In another implementation, the thermal ground provides a cushion upon which the encased electronic devices rests. The thermal ground 110 is similar to an electrical ground in that it is conductive and provides a single common base for absorbing energy. The thermal ground provides a single avenue through which heat from the heat-producing elements 120-123 is transferred to the heat dissipation element 106.

The thermal ground 110 when used as an enclosure can shield the computer components from electromagnetic energy, and can protect from lower RFI frequencies than a standard computer casing. The ground can also prevent electrostatic potentials. Electrostatic potentials can be created by electromagnetic fields from large motors, radiating antennas, or diathermy devices near the computer. Electrostatic potentials also can be created by varying signal potentials occurring at different chip-sites within the computer.

The heat dissipation element 106 receives heat from the thermal ground and dissipates it outside of the encased electronic device by any combination of conduction, convection (either forced or natural), and radiation. The heat dissipation element 106 is made of a thermally conductive material, for example, copper or aluminum. The heat dissipation element 106 can be made of any of the materials described herein for the making of flexible thermal connectors. The heat dissipation element can include additional cooling elements, for example, active thermonic elements, heat pipes, or fluid chiller. The heat can be dissipated by conduction, for example, to a fluid (e.g., a coolant) circulating through conduits (e.g., tubes) that are thermally coupled to the thermal ground. Heat can also be dissipated by radiation from the encased electronic device and the heat dissipation element 106.

The heat dissipation element 106 provides a large surface area for convective dissipation of heat into the environment. The heat dissipation element can have externally projecting features shaped like fins, blades, rudders, sheets, or the like. Optionally, the heat dissipation element can include a hairy heat exchanger. In one implementation, the hairy heat exchanger is made from thermally conductive and flexible fibers. One end of the bundle is thermally coupled to the thermal ground. The other end of the bundle extends to the environment external to the encased electronic device and, furthermore, can be free floating (not attached to each other or to another structure) so that the fibers at the free floating end can be moved by natural convection. Alternatively, the fibers in the end of the bundle that extends to the environment can be encased in a polymer with a large surface and optionally with holes through the surface. The polymer can be moveable so that the fibers can be oriented to maximize heat loss.

The degree of heat dissipated by convection can be adjusted by changing the shape or size of the heat dissipation element. For example, increasing the surface area of the externally projecting features without changing their volume typically increases the degree of heat dissipated by convection.

The heat can be dissipated from the heat dissipation element 106 by passive convection, for example, due to naturally occurring air movement external to the computer. The heat also can be dissipated from the heat dissipation element 106 by forced convection, for example, air movements created by external fans and/or coolant being pumped through conduits (e.g., tubes) thermally coupled to the thermal ground.

The configuration of the system can be varied depending on the heat removal requirements of the encased electronic device. For example, the thermal connectors that provide conduction pathways can be made of more conductive materials, shortened, and/or have increased cross sectional area when the heat removal requirements increase.

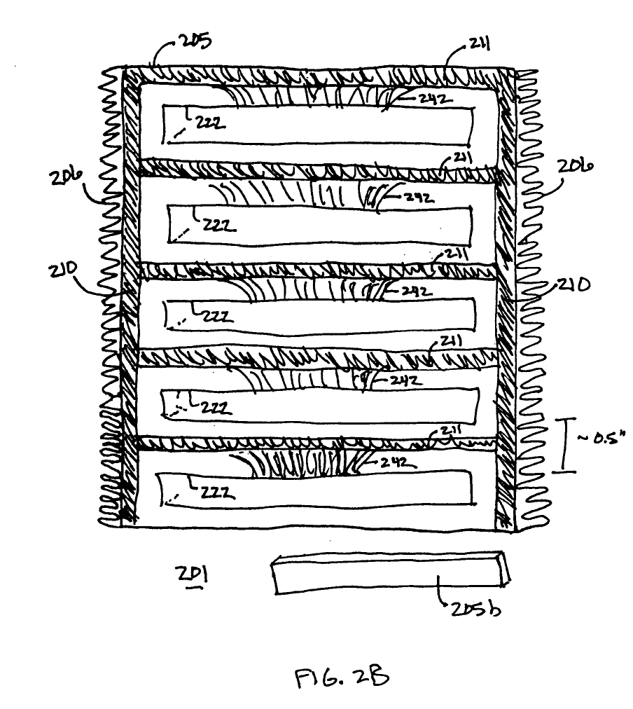

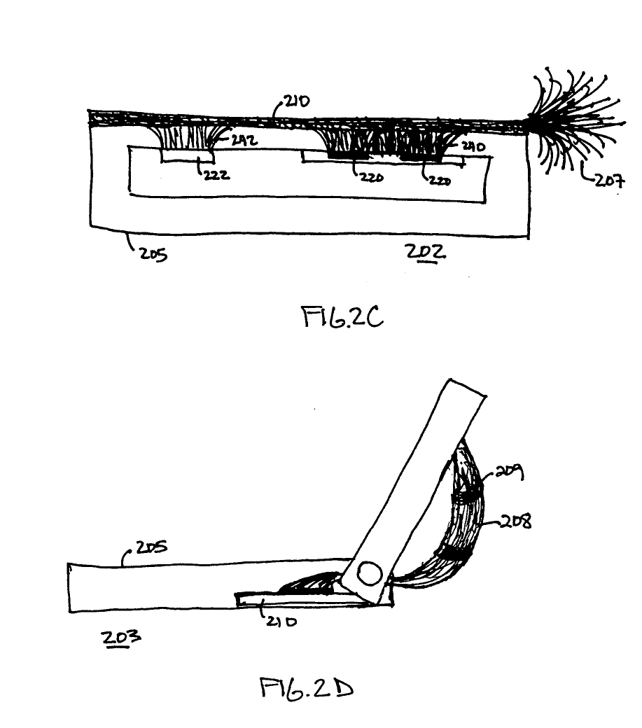

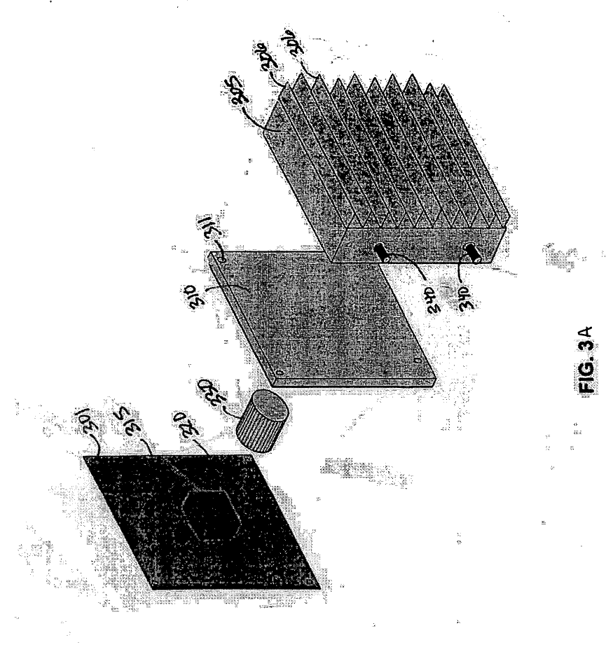

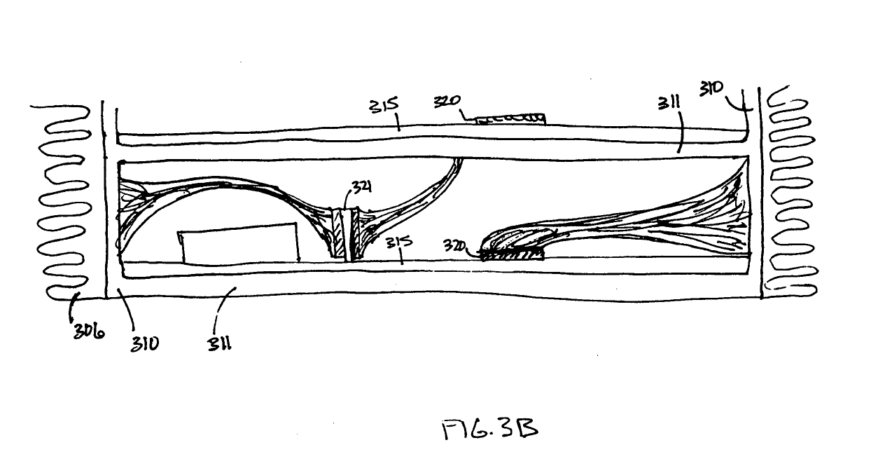

FIGS. 2A-F illustrate systems for removing heat from a computer without the use of fans or vents according to several implementations of the invention.

As shown in FIG. 2A, a system 200 for removing heat includes a casing 205 and a heat dissipation element 206 on the outside of the casing. As shown in FIG. 2A, the heat dissipation element can have parallel projecting planar segments each having two or more faces exposed to the air. The heat dissipation element can include one or more components and can be present on one, all, or any number of sides of the computer, for example, four sides of the computer as shown in FIG. 2A. A portion 205a of the casing 205 can be removed to provide access to the interior of the computer 200 and replaced to re-establish the encased computer. The system 200 for removing heat includes a thermal ground 210 that forms part of the casing 205 and upon which components of the computer can be mounted.

A printed circuit board 215 can be mounted to the thermal ground 210 so that the circuit board 215 faces the ground—that is, so that components mounted to the board face, for example a CPU 220, are sandwiched between the motherboard and the ground rather than being exposed to the interior of the computer. The circuit board 215 can be fastened to the ground 210 with spacers 217 to prevent contact between components on the circuit board 215 and the ground 210. A heat-producing component on the circuit board 215, for example the CPU 220, can be thermally coupled to the ground 210 by a thermal connector 230, discussed in more detail below.

A PC card 221 can be electrically attached to an electrical connector 222 on the backside of the circuit board 215 and coupled to the ground 210 by a thermal connector 231 that extends around the edge of the circuit board 215, as shown, or through a hole in the circuit board 215. A PC card includes any type of card that is connectable to an expansion slot, for example, a PCI, ISA, AGP, or VME slot. The thermal connector 231 can be a thermal strap, for example, a heat pipe or copper rod around or through the circuit board, and passes heat from the PC card to the thermal ground 210.

As shown in FIG. 2B, a system 201 for removing heat can have multiple units 222. The units 222 can be, for example, computer subsystems or components such as CPUs or drives. The drives can be, for example, computer hard drives, DVD drives, CD drives, optical drives, ZIP drives, tape drives, and floppy drives. For example, a system 201 can include multiple storage units 222 each of which is a hard drive. Also for example, a system 201 can include four hard drives and a DVD/CD-ROM drive, or any other combination of computer components.

The system 201 for removing heat from multiple units includes a casing 205 around some or all of the multiple units and a heat dissipation element 206 on the outside of the casing, as discussed above. The casing can include a removable door or plug 205b to provide access to a unit. The system 201 has a thermal ground 210 that forms part of the casing 205 and which is thermally coupled to multiple heat spreaders 211. A unit 222 or a heat-producing component in a unit 222 is thermally coupled to the thermal ground by being thermally connected to a heat spreader 211 of the system 201 with a thermal connector 242 such as a flexible cable, as discussed in more detail below. Heat spreaders 211 can be interspersed between stacked units 222 and each of the units 222 can be thermally coupled to the heat spreader 211 above or below the unit 222, as shown in FIG. 2B. The casing 205 and thermal ground 201, including the heat spreaders 211, can form a thermal rack for placement of units 222, for example, for placement of computers that make up a cluster. A unit 222 can be secured to a thermal spreader 211 with one or more bands that can be tightened around the unit 222 and thermal spreader 211.

Some but not all heat-producing components within a system for removing heat, for example, power supply components, can be thermally connected to the thermal ground and additionally encased, for example, in aluminum, to reduce convective transfer of heat from the components to air inside the system.

As shown in FIG. 2C, a system 202 for removing heat includes a casing 205 and a heat dissipation element 207 on the outside of the casing, for example, a hairy heat exchanger. The hairy heat exchanger can be protected with a cage, for example, an open mesh wire cage that permits air flow to the hairy heat exchanged but protects the heat exchanger from being touched, crumpled, or crushed by other objects. The heat dissipation element 207 can extend from one general location, as shown in FIG. 2C, or from multiple locations. The heat dissipation element 207 is thermally coupled to a thermal ground 210. One or more heat-producing components 220, 222, such as CPUs or computer chips, are thermally coupled to the thermal ground 210 by one or more thermal connectors 240, 242. As shown in FIG. 2C, a single thermal connector 242, 240 can provide a heat path for one heat-producing component 222, or for two or more heat-producing components 220.

As shown in FIG. 2D, a system 203 for removing heat can be a portable device, for example, a laptop computer that includes a casing 205 and a heat dissipation element 208 on the outside of the casing. The heat dissipation element 208 can be a hairy heat exchanger. The ends of the hairy heat exchanger outside of the casing can be secured, as shown, or can be splayed out, as shown in FIG. 2C. If the ends of a hairy heat exchanger outside of the casing are secured, the constituent cables or fibers can be fanned out, for example by operation of bands 209 (FIG. 2D), to improve heat exchange. The heat dissipation element 208 can be folded around the case 205 of the portable device when the device is not in use. The system 203 has a thermal ground 210 that is thermally coupled to the heat dissipation element 208 and which can be thermally coupled to one or more heat producing devices such as the CPU and disk drive, for example, as discussed herein.

In an alternative embodiment of a system for removing heat from a portable device, a thermal ground that is thermally connected to a heat dissipation element, such as a hairy heat exchanger, is placed under the portable device. The thermal ground and heat dissipation element can be encapsulated in a pad, with fibers that extend from a location at the surface of the pad that corresponds to hot spots on the bottom of the laptop to outside the pad, where they form a heat dissipative element.

An exploded view of a system for removing heat from a heat-producing element, according to another aspect of the invention, is shown in FIG. 3A. A heat-producing element, for example, a CPU 320, can be mounted on a circuit board 315 and can be thermally coupled to a thermal ground 310 with a thermal connector 330. The board 315 can be fastened to the ground 310, for example, with pins attaching each of one or more connectors 317 on the board to each of one or more connectors 318 on the ground 310 so that the thermal connector 330 is held tight against the CPU 320 and the ground 310. The ground 310 is thermally coupled to the heat dissipation element 306. The heat dissipation element 306 can have externally projecting features that form a series of projecting prism-shaped segments, each segment exposing two rectangular faces to air outside the computer. The heat dissipation element 306 can include conduits 340 for the circulation of fluid through the heat dissipation element 306.

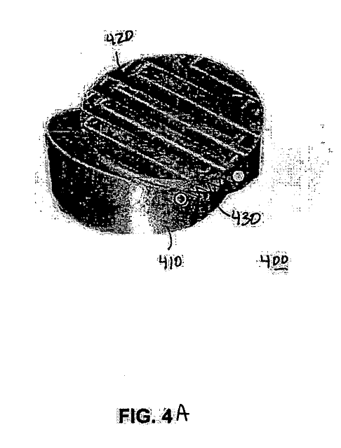

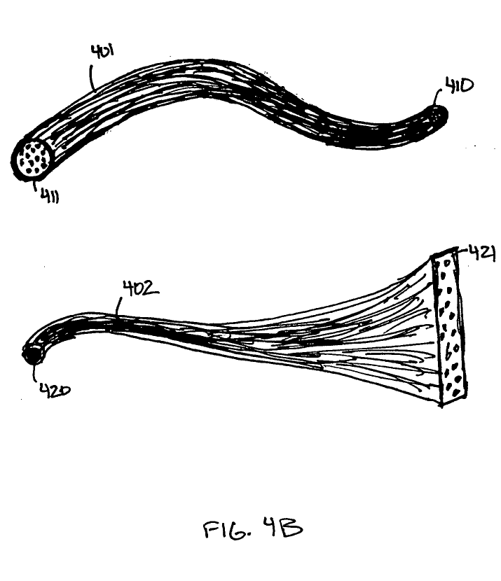

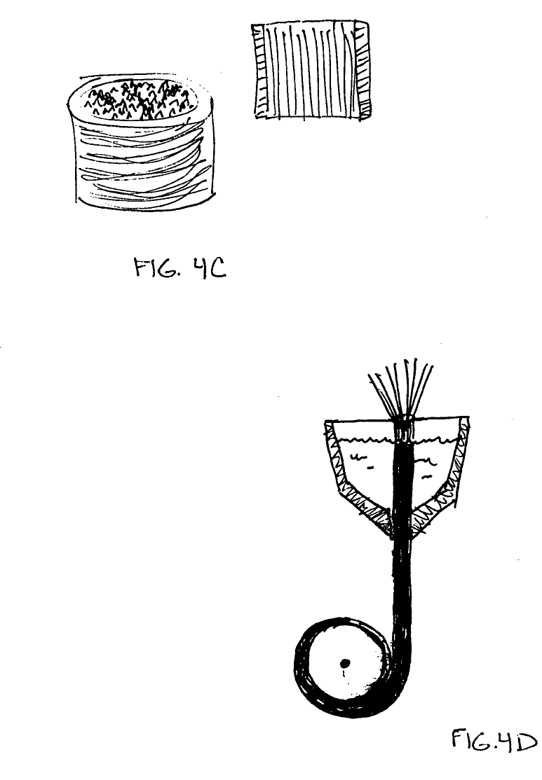

The thermal ground 110, 210, 310 can be coupled to a heat-producing element, for example, a CPU 120, 220, 320, PC card, 121, 221, disk drive 122, 222 or power supply 123, with a thermal connector 400 that includes two or more joined segments 410, 420, as shown in FIG. 4A. Each segment 410, 420 of the thermal connector 400 can move relative to the other 420, 410 while maintaining contact between the segments 410, 420. For example, a top segment 420 can slide up the slanted face of a bottom segment 410 so that the two segments 410, 420 form a cylinder. The segments can be held against each other with a spring 430 attached to each segment and crossing the plane of contact between the segments. In the implementation shown in FIG. 4A, the thermal connector 400 can move with three degrees of freedom and can adjust for differences in the distance, parallelism and contact pressure between a heat-producing element, for example, a CPU 120, 220, 320, and the thermal ground 110, 210, 310. This movement of the two or more joined segments maintains thermal coupling between the heat-producing element, for example, a CPU 120, 220, 320, and the thermal ground 110, 210, 310 if, for example, the ground expands and contracts due to changes in its temperature.

A side-view of a system for removing heat from a heat-producing element, according to another aspect of the invention, is shown in FIG. 3B. A heat-producing element, for example, a CPU 320 or a memory chip 321, can be mounted on a horizontally oriented circuit board 315 and can be thermally coupled to a vertically oriented thermal ground 310, for example, with a flexible thermal connector 330. The thermal ground 310 is thermally coupled to the heat dissipation element 306. A heat-producing element, for example, a memory chip 321, also can be thermally coupled with a flexible thermal connector 331 to a heat spreader 311 that is thermally couple to the thermal ground 310, also as shown in FIG. 3B.

A flexible thermal connector 330 can bend without breaking. It can absorb shock applied to a system and, if of an appropriate size and shape, can be guided around components in a system. A flexible thermal connector is typically cable-like and can be several feet in length. The shape and size of the cross-section along the length of a flexible thermal connecter can vary. For example, as shown in FIG. 4B, a flexible thermal connector 401 can be cylindrical with increasing circumference from one end 410 to the other end 411, for example, from an end couple to a heat-producing element to an end coupled to a thermal ground. Also for example, a flexible thermal connector 402 can be cylindrical at one end 420 and rectangular at the other end 421.

A flexible thermal connector 330, 401, 402 can be made from generally linear elements such as fibers, ribbons, tapes, or from particles or pieces of any combination of materials having high thermal conductivity, including for example fibers made of pitch based carbon fiber, diamond, vapor grown carbon fibers (VGCF), or carbon nanotubes. The flexible thermal connector can include, for example as filler material in the form of wires or powders, silver, gold, copper, aluminum, other metals, graphite, carbon black, emerald, sapphire, beryllium oxide (BeO), boron nitride (BN), silicon carbide (SiC), and aluminum nitride (AIN). Alternatively, fibrous materials can be coated with such highly conductive materials, including for example diamond, carbon nanotubes, vapor grown carbon, and boron nitride. To achieve high thermal transfer, high fiber loads, e.g. 70% or more, can be used. When using fillers, a load of less than 80% is preferred to avoid creation of a thick paste and for ease of processing.

The flexible thermal connector can be made from a group of generally linear elements, the orientation of which can vary. For example, the linear elements can form one or more spirals in one or more orientations and position. Preferably, the architecture of the flexible thermal connector is such that thermal conduction is greatest in the longitudinal direction of the thermal connector and directional. For example, fibers can be tightly packed at one end to improve heat absorption and can be more loosely packed at the other end to enhance heat transfer. Multidirectional connectors can be used to spread heat and can be made, for example, from woven fabrics, lay-ups, and fiber felts.

The flexible thermal connector can be made from chopped linear elements, particles, or pieces that are packed in tube that forms a protective outer layer. The chopped linear elements, particles, or pieces can be bundled, fused, or sintered to create a linear or tubular matrix of highly conductive material with the coating of other highly conductive material, as shown in FIGS. 4C and 4D. A conductive binder, such as graphite paste, silver paste, or carbon nanotube paste, can be used to consolidate the chopped linear elements, particles, or pieces into a polymer or metal matrix. Maximum compacting of the matrix can be achieved by a fuse or sinter process, for example, a standard pellet type press or, alternatively, compacting can be reduced to provide flexibility as appropriate. The bundle can become a single integrated structure.

The flexible thermal connector can be made by batch casting with a form or mold that distributes fiber according to a specific design. The flexible thermal connector can be formed by arranging fibers using bindings and weights and then firming the arrangement, for example, with potting material such as plaster. The flexible thermal connector can be made by calendar coating, continuous extrusion or knife type coating.

Preferably, the flexible thermal connector has a protective layer, such as a cable sheath or jacket, that surrounds the flexible thermal connector lengthwise and provides thermal insulation. The protective layer can be made, for example, from polymerical materials such as polyvinylchloride (PVC), nylon, polyethylene, polypropylene, or polyester. The protective layer can be made from expanded or foamed polymer materials, such as polyurethane foam, long density polyethylene (LDPE), closed cell foams, and sponge rubber. The protective layer can be made from polymers that include fillers such as natural cork, silica aerogel, Cab-O-Sil, mica, or wood flour. Thin films of ceramics such as zirconium dioxide or silicon dioxide can also be used.

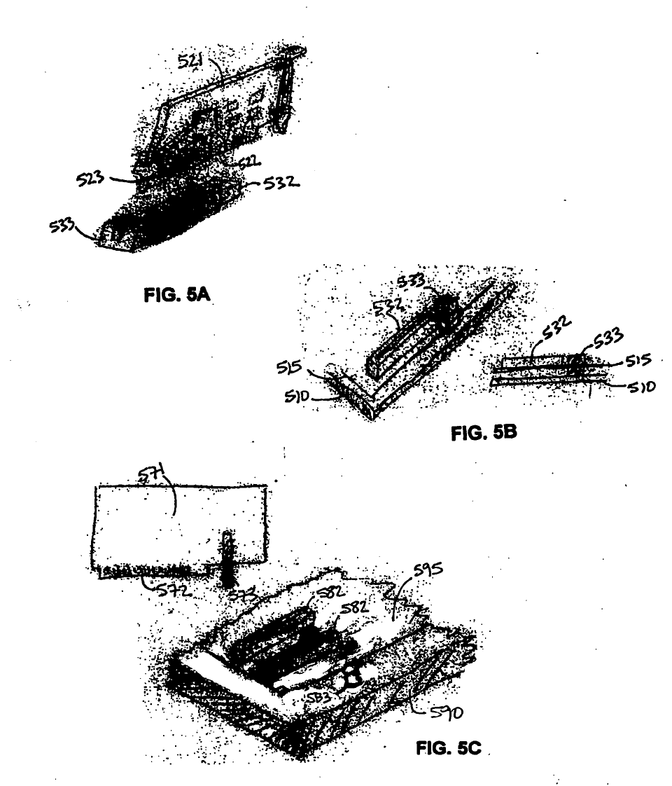

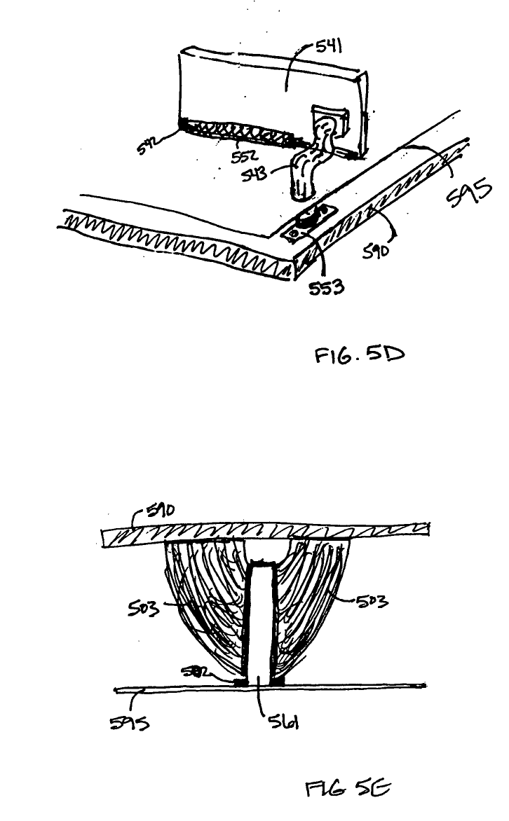

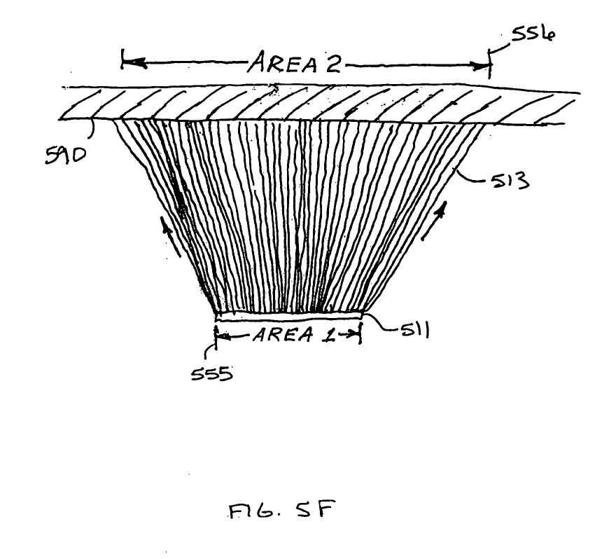

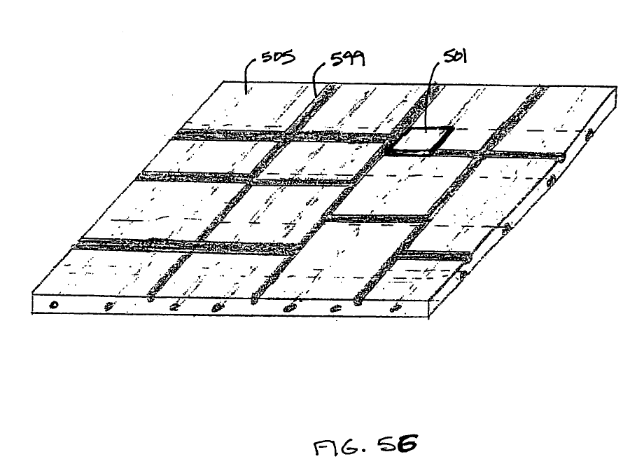

A heat-producing electronic device, for example, a PC card 121, 221, can be thermally coupled to a thermal ground 130, 230 with a combined thermal and electrical interface as shown in FIGS. 5A-5D. APC card 521, 571, 541, 561 has an electrical connector portion 522, 572, 542, 562 that can be inserted into an electrical slot or plug 532, 582, 552, 502 on a circuit board 515, 595. The PC card 521, 571, 541, 561 can also have a thermal connector 523, 573, 543, 563 that is secured and thermally connected to the PC card 521, 571, 541, 561 and which can be coupled to a thermal ground 510, 590.

As shown in FIGS. 5A-B, the thermal connector 523 can include a wedge-shaped extension insertable into a thermal plug 533 that is secured and thermally connected to the thermal ground 510. The thermal connector 523 and thermal plug 533 are made of thermally conductive material. As shown in FIG. 5C, the thermal connector 573 can be a small rod (e.g., ¼″ diameter) that extends through the circuit board 595 and inserts into a socket 583 in the thermal ground 590. The socket can be a simple hole (e.g., ¼″ diameter and ⅜″ deep) in the thermal ground 590. The thermal connector 523, 573 and receptacle plug 533 or socket 583 permit easy insertion and removal of the PC card from the circuit board 595.

As shown in FIG. 5D, the thermal connector 543 can be a flexible cable that is secured to the circuit board 595 and which extends though the circuit board and is connected to the thermal ground 590, for example, with a collar. As shown in FIG. 5E, the thermal ground 590 can be opposite the face of the circuit board 595, such that the PC card 561 is between the thermal ground 590 and the circuit board 595; The thermal connector 503 can be made of flexible fibers that are secured to the thermal ground 590 and which form a groove into which the PC card 563 fits. The thermal connector 503 can be manufactured such that it exerts pressure against the sides of the PC card 563 when the PC card is inserted into the groove in the thermal connector 503, thereby improving thermal connectivity between the PC card and the thermal connector.

As shown in FIG 5F, the thermal connector 513 can be a bundle of fibers extending from a heat-producing element 511 to a thermal ground 590. The bundle of fibers can be made, for example, of anisotropic high conductivity carbon fiber. The bundle of fibers can be sufficiently flexible to permit absorption of some portion of a physical shock or jolt applied to the system, such as might occur if the system was jarred during movement or accidentally impacted by another object. The thermal connector 513 can be thermally coupled to the heat-producing element 511 such that the thermal connector and heat-producing element make contact over a first area 555, and can be thermally coupled to the thermal ground 590 such that the thermal connector and thermal ground make contact over a second area 555. The first area 555 can be smaller than the second area 556, such that heat conducted from the heat-producing element 511 to the thermal ground 590 is spread over a larger area 556 of the thermal ground than the area 555 of the heat-producing element coupled to the thermal connector. For example, the fibers in the bundle of fibers can diverge from an area 555 of contact between the thermal connector 513 and the heat-producing element 511 to a larger area 556 of contact between the thermal connector 513 and the thermal ground 590, such that the thermal connector 513 spreads or dissipates heat. As shown in FIG 5G, a circuit board 505 can include thermally conductive vias 599 to transfer heat from one region of the circuit board to another. For example, heat can be transferred from a CPU 501 on the circuit board to the vias and hence to a thermal ground.

When the thermal connector 523, 573, 543, 563 is connected to the thermal ground 510, 590, a conduction pathway is created. The conduction pathway can conduct heat from the PC card 521, 571, 541, 561 to the thermal ground 510, 590. As shown in FIG. 5C, electrical plugs 532, 582 and corresponding thermal plugs or sockets 533, 583 for two or more PC cards 571 can be placed close together on the circuit board 515, 565, because heat is removed from the PC cards through the conduction pathway rather than dissipating into the air inside the computer, thereby potentially reducing the required size of the computer.

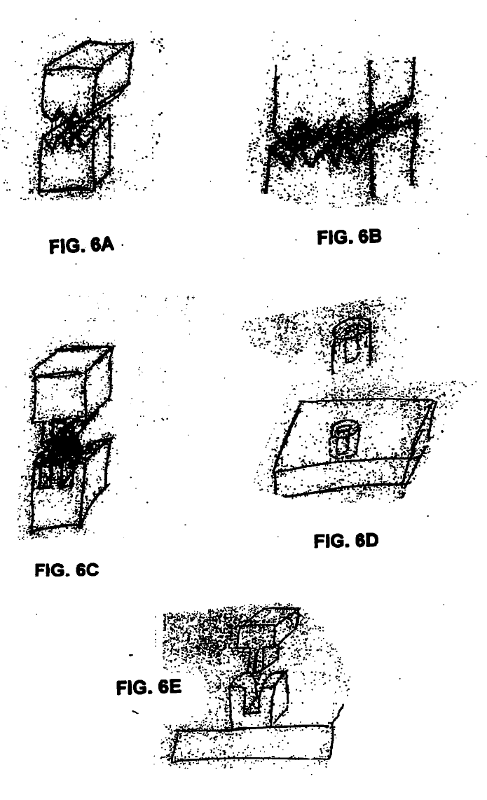

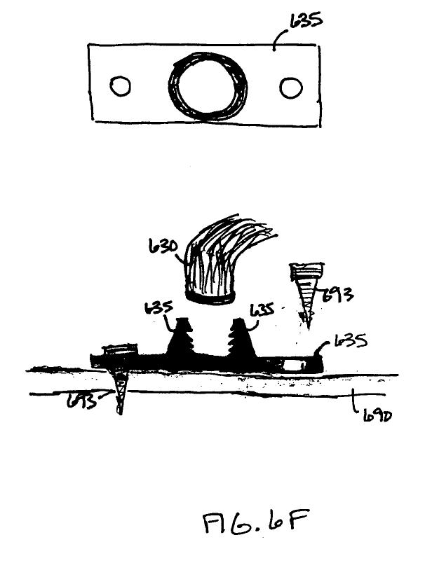

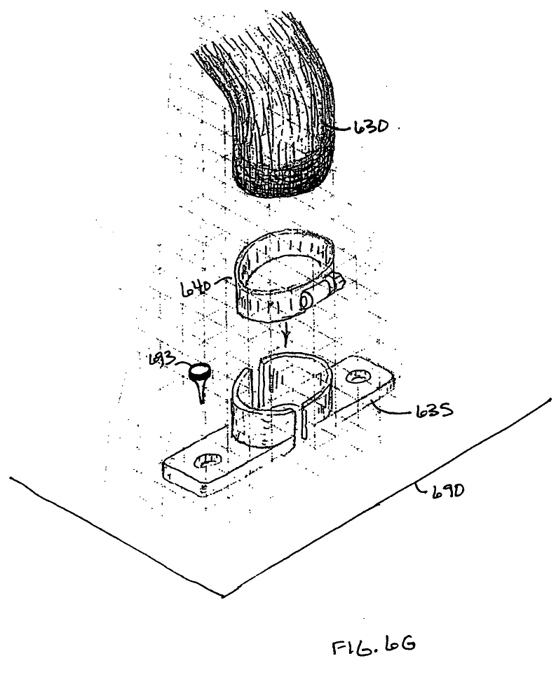

In general, a conduction pathway can be provided by two or more connectable segments, where one segment is thermally connected to a heat-producing element and a connectable segment is thermally connected to or included in the thermal ground. As shown in FIGS. 6A-6E, the connectable segments can be shaped in many different ways. Typically, the connectable segments interconnect on multiple planar or cylindrical surfaces to maximize the rate of heat transferred from one segment to the other.

As shown in FIGS. 6F-6G, one connectable segment can be a flexible cable 620 as described above and the other connectable segment can be collar 635, 636, 637 into which the end of the flexible cable 630, 631 is inserted. Generally, the shape of the collar will be similar to the shape of the end of the cable. For example, if the cross-section of the cable is round, the collar can be round; if the cross-section of the cable is square, the collar can be square. The interior edges of the collar 635 can be serrated or threaded to help secure the cable 630 in the collar 635. Alternatively, a hose clamp 640, clip, or similar device can be tightened around the collar 636 after an end of the cable 630 is inserted into the collar 636 to secure the cable 630 to the collar 636. The collar 635, 636, 637 can be connected to a thermal ground, for example, with pegs or screws 693 or by soldering and can be used to thermally connect the cable to the thermal ground. The collar can be connected to a heat-producing device such as a CPU and can be used to thermally connect the cable to the heat-producing device. All connections between the connectable segments, the thermal ground, and/or the heat-producing device are preferable under pressure to ensure thermal coupling.

The two end lateral surfaces of the cable can be plated with a highly conductive material, for example, the same material used for fusing the fiber. In this plating process, high thermal conductivity is achieved for the complete bundle and also the interface between the bundle and the thermal ground. The thermal ground can also have a plating of the same metal/material to provide an interface that achieves the lowest thermal resistance. The above described processes can be used for making all components of the heat removal system. For example, any thermal connector can be dip-coated in a molten bath of highly conductive material or coated with a highly conductive material by spray coating, electrostatic spray coating, chemical vapor deposition (CVD), or physical vapor deposition (PVD). Without intending to be bound by theory, thermally conductive material that is applied to the lateral surfaces of a flexible thermal connector may infiltrate fibers or constituents of the flexible thermal connector to some degree, for example, due to wicking or capillary action.

Alternatively or in addition to the use of plating, a pad of thermally conductive material can be placed between thermal connectors and the thermal ground or a heat-producing device to improve the contact and thermal conductance between the thermal connector and the thermal ground or heat-producing device. Such thermal pad is preferably flexible and/or compressible to permit maximum contact upon the exertion of pressure or force, and can be as thin as a few thousandths of an inch. The thermal pad can have a polymer matrices, such as polyvinylchloride (PVC), nylon, low density polyethylene (PE) or polyurethane, with high conductivity fillers such as carbon nanotubes, diamond, fibers made of ultra high modulus pitch or polyacrylnitrile (PAN), boron nitride, aluminum nitride, beryllium oxide, emerald, sapphire, carbon black, silver, copper, gold, and graphite. The thermal pad can be a gel, and can be applied at the junctions of a conductive pathway, for example, where a thermal connector is coupled to a thermal ground. A large pad or blanket of thermally conductive material can be placed between a circuit board and a thermal ground, preferably in conjunction with an electrically insulative layer, for example, applied to the circuit board or the thermal pad, to prevent electrically shorting.

An electrical insulation layer can be used between thermal connectors and the thermal ground or a heat-producing device to prevent the flow of electricity while permitting the transfer of heat. An electrical insulation layer can be applied, for example, to the ends of flexible thermal connectors by spray coating, chemical vapor deposition (CVD), physical vapor deposition (PVD), spray coating, or electrostatic spray coating. Alternatively, an electrical insulation layer can be a thin disc or sheet of material that is inserted, for example, between the thermal connector and the thermal ground before securing the thermal connector to the thermal ground. An electrically insulating layer can be combined with a pad of thermally conductive material, for example, by incorporating a thin layer of electrically insulating polymer to both sides of the thermal pad or to sheets of thermally conductive material from which thermal pads are cut, for example, by tape or roll casting.

Convective heat losses from heat-producing components can be reduced and heat-producing components that have moving parts, for example, a disk drive, can be silenced and protected from mechanical vibrations as well as chemical or other contamination (e.g., water), while still providing an avenue for heat removal, by surrounding them with a flexible elastomer material or shock-absorbing foam while maintaining a conduction pathway between the component and a thermal ground. In this way, the component is insolated from vibration, but heat flows from the component to the thermal ground.

The components can be coated with a nonremovable elastomer, or surrounded with a removable elastomeric jacket. The elastomer can be polyalkylene, polyurethane, silicone rubber or any other solid elastic material with a thermal conductivity from around 0.05 W/mK or better (where K is degrees Kelvin). For a 12-watt disk drive, a conductivity of about 1 W/mK is preferred. The elastomer can be filled with metal, carbon fibers, graphite pitch, or carbon black to increase thermal conductivity. The elastomer can be filled with glass spheres or talc to increase the acoustic absorption and attenuation. Multiple layers of elastomer can be user. For example, a layer of firm rubber can cover a component, for example a disk drive, and a layer of less firm rubber can surround the layer of firm rubber.

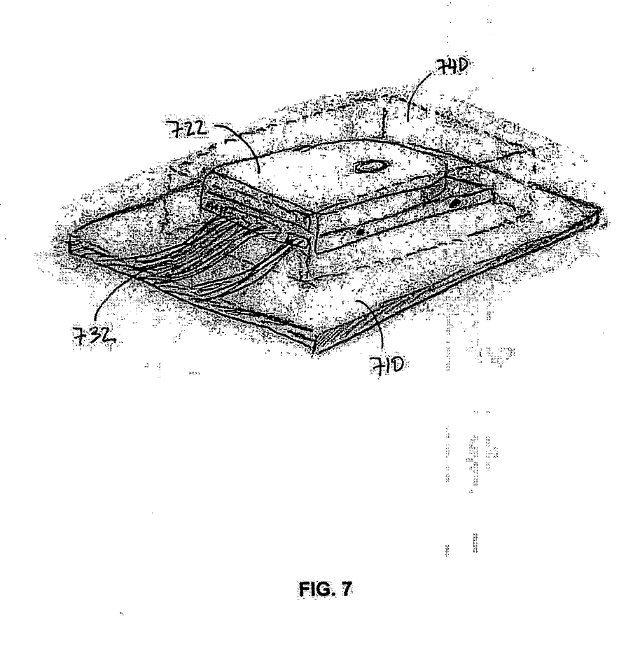

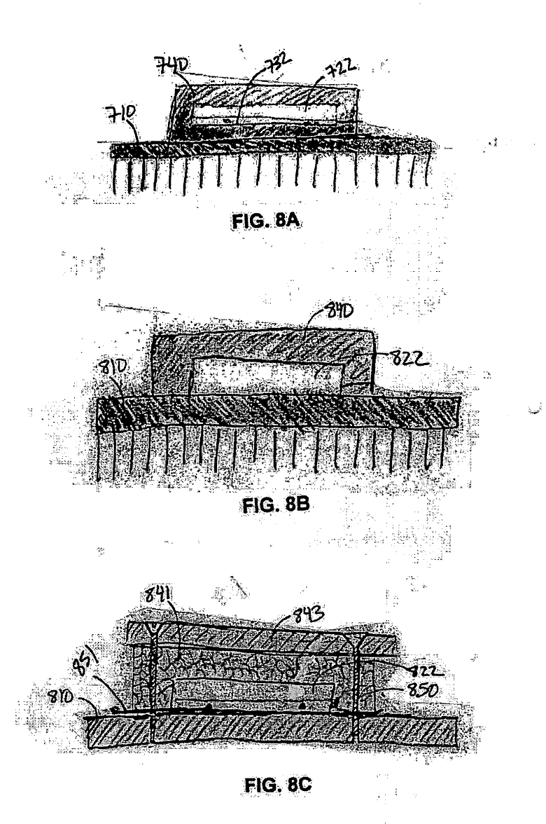

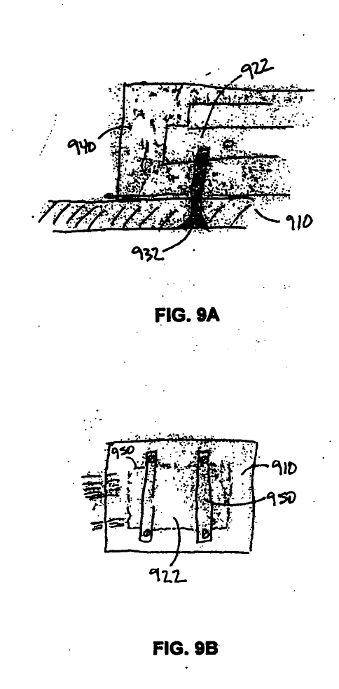

As shown in FIGS. 7 and 8A, a disk drive 722 can be surrounded on all sides by an elastomer 740. The elastomer absorbs noise produced by the disk drive and mechanical shocks from outside the computer, and can prevent chemicals from reaching the disk drive. Cables 732 can extend through the elastomer to electrically connect the component to the rest of the computer. The disk drive 722 is thermally coupled to the thermal ground 710, which is a plate in the example shown. A disk drive can be thermally coupled to the thermal ground with, for example, a thermal strap, which can extend through the elastomer. A disk drive can be thermally coupled to the ground with a pin or screw, for example, screw 932 (FIG. 9A) which can extend from the thermal ground 910, through the elastomer 940, and into the disk drive 922. A disk drive can be thermally coupled to the thermal ground by, for example, direct contact on one side and surrounded by elastomer on the remaining sides. FIG. 8B shows an example of this implementation. The disk drive 822 is thermally coupled to the thermal ground 810 by direct contact on one side and surrounded by elastomer 840 on the remaining sides. In this implementation, the connecting ribbons can be connected as needed.

The use of screws to thermally couple a disk drive to a thermal ground can expose the disk drive to mechanical vibrations and may provide a path for emission of noise. As shown in FIG. 8C, a high thermal conductor, for example, solid rubber 851, can be placed between the disk drive 822 and the thermal ground 810, and a good acoustic absorber, for example, a foam rubber 841, can surround the remaining sides. A second ground 843 can be placed over the foam 841 and secured to the thermal ground 810 with pins or screws 850 that pierce the layer of rubber 851 to fasten the disk drive 822 to the ground 810. Alternatively, the disk drive 922 can be fastened to the thermal ground 910 with one or more straps 950 that extend over or through the elastomer coated disk drive 922 and are secured to the ground 910, as shown in FIG. 9B.

The invention does not require the removal of hot air from inside a computer. Hot air may be produced inside the computer by the convective dissipation of heat directly from the heat-producing elements. Hot air can be removed, for example, with fans inside the computer that move hot air away from the heat-producing elements and vents that allow the air to circulate in and out of the computer.

Reliance on fans can affect performance and may jeopardize the viability of the computer. For example, the efficiency of a fan usually decreases as the result of normal mechanical wear, which can increase the heat produced by the fan and decrease the air flow. The efficiency of fans also decreases due to the accumulation of dust and other contaminants, which reduces airflow and hence cooling produced by the fan, and which may create moving electrostatic fields adversely affecting the performance of nearby electronic devices. Fans also generate internal mechanical resonance with harmonic vibrations that can affect performance, for example, of hard drives. If a fan fails, a computer may overheat and be irreparably damaged. Even if the computer is undamaged, it must be opened for maintenance of the fans, which risks accidental damage to other components.

The above described system removes heat produced inside a computer without reliance on convective dissipation inside the computer and subsequent removal of the resulting hot air by fans. The system conducts heat to a heat dissipation element outside the computer, which transfers or dissipates the heat outside the computer. Thus, the system can remove heat from a computer without the noise that fans produce—that is, the computer can be operated in silence. The system also can remove heat from a computer that does not have vents, including a computer that is sealed to minimize or prevent the entry of air, water, and/or contaminants into it.

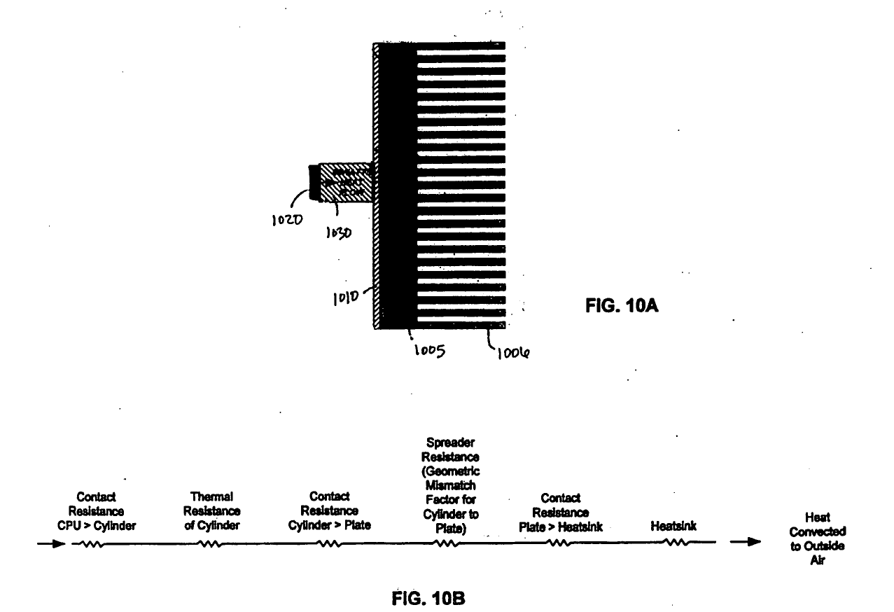

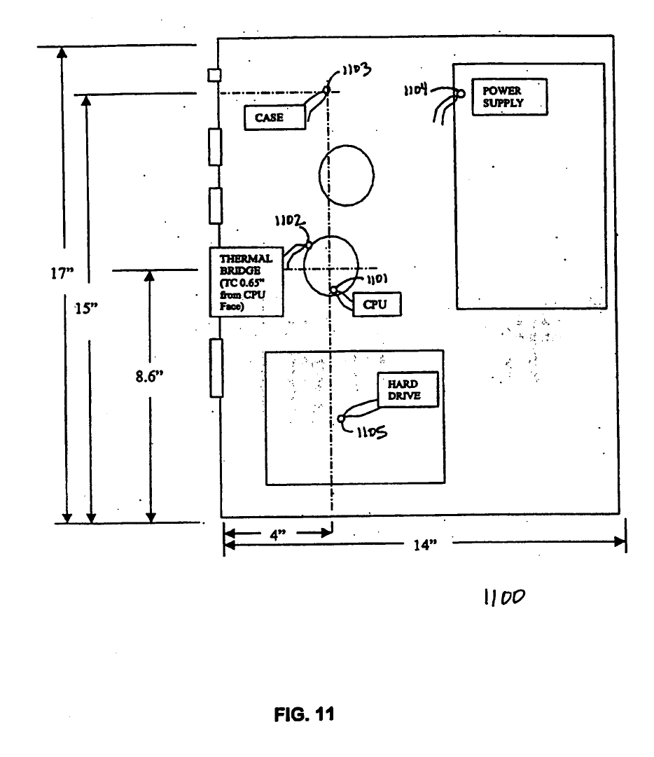

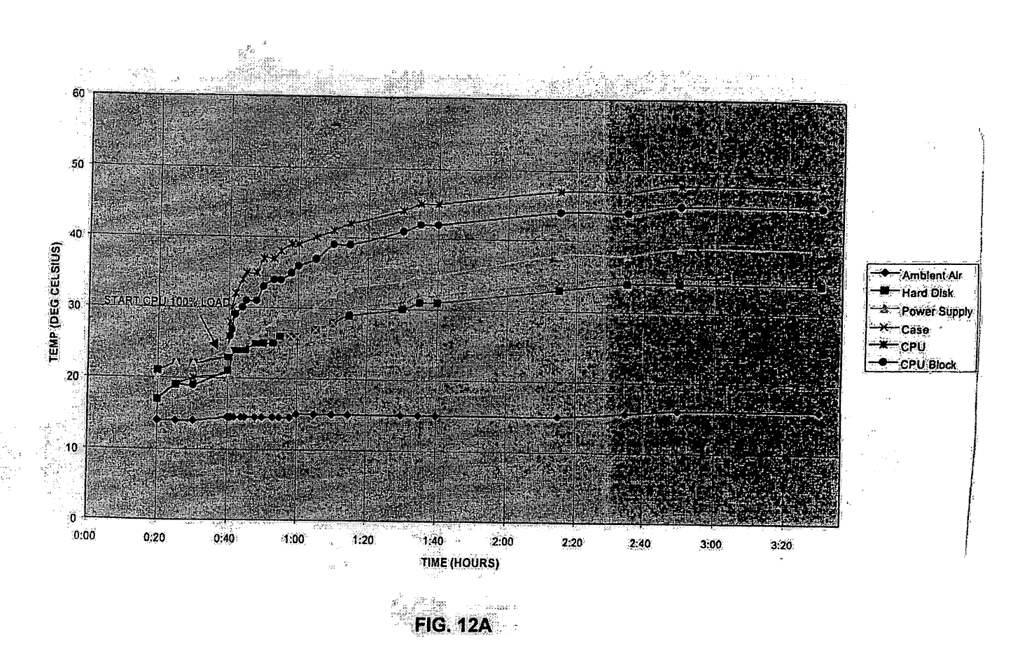

A mathematical thermal model was developed to demonstrate the effective removal of heat from an encased electronic device in one implementation of the invention. As shown in FIGS. 10A-10B, the model is for heat that flows from a CPU 1020 across an interface to a thermal connector (“cylinder”) 1030, then across an interface to a thermal ground 1010, then across an interface to a heat dissipation element and finally into the environment. The physical properties and parameters used in the mathematical model are given below in Table 1.

TABLE 1

| Thermal Conductivity | Area | Heat Path Length |
|---|---|---|
| $Kalum := 240 \frac{W}{m \cdot K}$ | Acpu := 0.0015 m² | Lpaste :=2.54₁₀⁻⁵ m |
| $Kcyl := 240 \frac{W}{m \cdot K}$ | Acyl := 0.002 m² | Lcyl := 0.0254 m |
| $Kplate := 240 \frac{W}{m \cdot K}$ | Aplate := 0.154 m² | Lplatehtsnk :=0.017 m |
| $Kthermgrease := 1 \frac{W}{m \cdot K}$ | | |

In the mathematical thermal model, conductive heat flow is one-dimensional and steady state, and criteria are defined as follows. The CPU has a power dissipation of 75 watts. The thermal connector is centered on the thermal ground. Thermal coupling grease at a thickness of about 1.0 mm is considered to be used at interfaces between components. The thermal ground is an integral part of the casing. Heat is dissipated by the heat dissipation element by natural convection. Heat produced by a power supply, PC cards, and disk drives is not part of the model.

The model describes the thermal conductivity for each device in the heat flow path as a parameter K_{device}, where K is degrees Kelvin. The basic thermal resistor for one-dimensional steady-state conduction heat flow for each device is then

$${R}_{device} := \frac{Length}{Area \cdot {K}_{device}} Where \text{:} {K}_{device} = , \frac{Watts}{meter \cdot Kelvin} \\$$

such that the units for R_{device} are

$${R}_{devices} := \frac{{s}^{3} \cdot K}{kg \cdot {m}^{2}}$$

The following linear thermal resistances were calculated based on resistance of materials and dimensions of the relevant component or feature. The first contact resistance R_{cpucyl} for the interface between the CPU 1020 and the thermal connector is

$${R}_{cpucyl} = 0.017 \frac{{s}^{3} K}{kg {m}^{2}} ,$$

The thermal resistance R_{cyl} of the thermal connector is

$${R}_{cyl} = 0.053 \frac{{s}^{3} K}{kg {m}^{2}} ,$$

The contact resistance R_{cylplate} for the interface between the thermal connector 1030 and the thermal ground 1010 is

$${R}_{cylplate} = 0.013 \frac{{s}^{3} K}{kg {m}^{2}} ,$$

The thermal resistance R_{spreader} of the thermal ground 1010 is

$${R}_{spreader} = 0.084 \frac{{s}^{3} K}{kg {m}^{2}} ,$$

The contact resistance Rₚₗₐₜₑₕₜₛₙₖ for the interface between the thermal ground 1010 and the heat dissipation element 1005 is

$${R}_{platehtsnk} = 1.649 \times {10}^{- 4} \frac{{s}^{3} K}{kg {m}^{2}} ,$$

The total thermal resistance Rₕₑₐₜₛₙₖ for the interface between the heat dissipation element and ambient air is:

$${R}_{heatsnk} = 0.3 \frac{{s}^{3} K}{kg {m}^{2}} ,$$

If the CPU is running at 100% with a power output Q of 75 Watts (W), the temperature drop ΔT across each resistance is given by ΔT=Q_{cpu}×Rₜₕₑᵣₘₐₗ, where Q_{cpu}=75 W. The one-dimensional steady-state conduction model is represented by the equivalent thermal circuit that impedes the heat flow of the CPU's 75 W of energy, as shown in FIG. 10B. The input is at the left and the heat is flowing passively through the computer, being dissipated by convection and radiation at the right. The sum ΔTₜₒₜₐₗ of all the above thermal resistances in FIG. 10B is:
ΔTₜₒₜₐₗ:=ΔT_{cpucyl}+ΔT_{cyl}+ΔT_{cylplate}+ΔT_{spreader}+ΔTₚₗₐₜₑₕₜₛₙₖ+ΔTₕₑₐₜₛₙₖ
=1.27+3.969+0.953+6.308+0.012+22.5=35.011K

If the ambient temperature, T_{ambientC}, is 16° C.; the absolute ambient temperature T_{ambient} is: T_{ambientK}=T_{ambientC}+273K=289 K, and the temperature of the CPU is found as T_{cpu}=ΔTₜₒₜₐₗ+T_{ambient}=324.011K. Converting the CPU temperature T_{cpu} to degrees Celsius gives the theoretically calculated value of the CPU temperature as follows: T_{cpuC}=T_{cpu}−273K=51.011° C. In comparison, the experimentally measured value of the CPU temperature is: 48° C. Thus, the theoretical thermal model is in reasonably close agreement with the experimentally measured values for CPU temperature.

The thermal model can be used to suggest improvements to the design of a system for removing heat from an encased electronic device according to the invention. For example, the model indicates that most of the thermal resistance in the system for heat removal is at the interface between the heat dissipation element and the air (ΔT=22.5K). If very low velocity air (4 m/s or 750 linear feet per minute or LFM) is used to cool the heat dissipation element, the resistance of the heat dissipation element is lowered from 0.3 to 0.084−S³·K/(Watt). According to the model, the use of active external cooling results in a drop in CPU temperature from 51° C. to 34.8° C., which is only 18.8° C. above normal or ambient air temperature.

The results of a Flowmeric thermal simulation were consistent with the steady-state conductive thermal model described above. Temperatures measured on one implementation of the invention further demonstrate the effective removal of heat from an encased electronic device according to the invention, and also verify the theoretical thermal model and simulation described above.

Temperature measurements were taken at various locations on a prototype computer embodying the invention and having specifications as follows. The case is 4¾ inches in width, 17 inches in height and 14 inches in length. By comparison, the typical minitower computer case is 8 inches in width, 17.25 inches in height, and 19 inches in length. The thermal ground plate of the prototype has an area of 3,000 square inches and a thickness of less than 0.5 inches. The weight includes 27.5 Lbs of Aluminum and the total weight is about 32 Lbs. The electronic components include an Intel® D845GRG, a micro-ATX (9.60 inches by 8.20 inches), support for an Intel® Pentium® 4 processor in a μPGA478 socket with a 400/533 MHz system bus, an audio subsystem for AC '97 processing using the Analog Devices AD1981A, codec featuring SoundMAX Cadenza, Intel® Extreme Graphics controller, USB, 100 Megabits onboard Ethernet, low profile RAM of 256 Meg PC2100 DDR ram, an Intel P4 2.26 Gigahertz CPU with 533 Mhz Front Side bus, a Fujitsu MPD3064AT 6 Meg disk drive. The power supply is 150 Watt ATX12V power compatible, with an input of 100 240 Vac, 47 63 Hz, 3 Amp and an output of +5 Vdc @26 A, 3.3 Vdc @8 A, −12 Vdc @1 A, +12 Vdc @6 A. There are no additional PCI or AGP slots. The form factor is a base-line 1 U with overhead space requirements of approximately 3 inches. The box can be rack mounted allowing it to support any special usage, for example 3 D visualization. The externally projecting features of the heat dissipation element are of length 16 inches and width 13.92 inches with a surface area of 3132.8 square inches and a weight of 24.8 lbs.

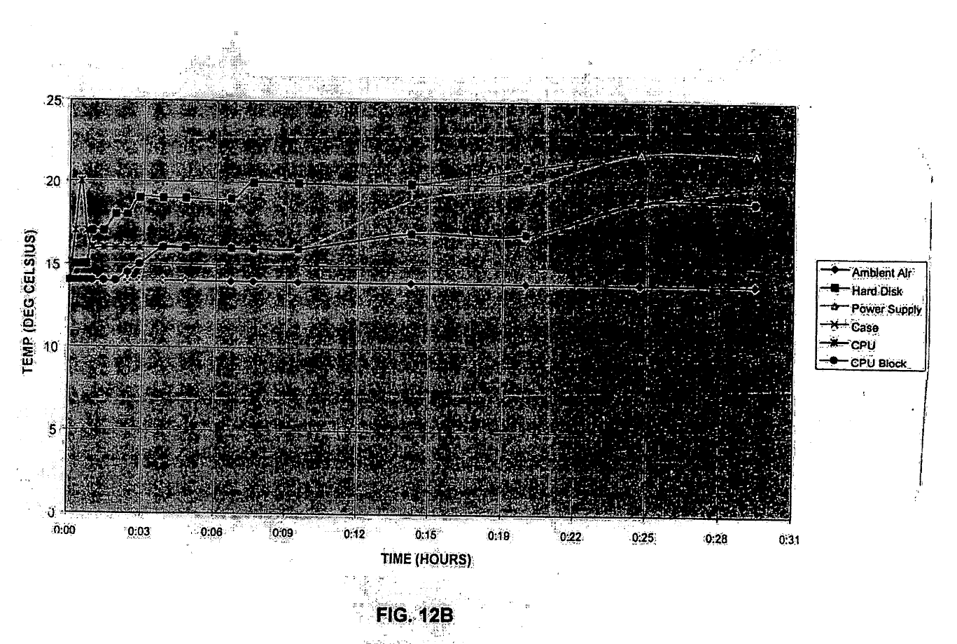

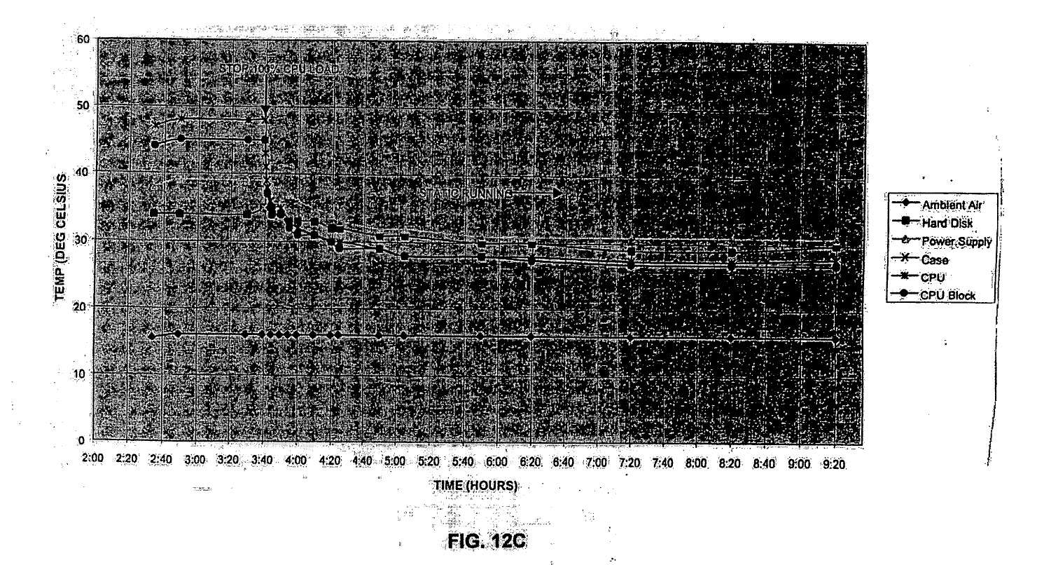

Temperatures were measured over time using a chronograph and a KRM meter with an internal electrical 0° C. cold reference junction and type K Chromel-Alumel 10 mm bead thermocouples. As shown in FIG. 11, measurements were taken on the system 1100 for removing heat at the following positions: on the CPU face 1101, at the thermal connector (i.e., the thermal bridge) 1102, at the heat dissipation element 1103, at the power supply 1104, at the hard disk 1105, and for air outside the computer.

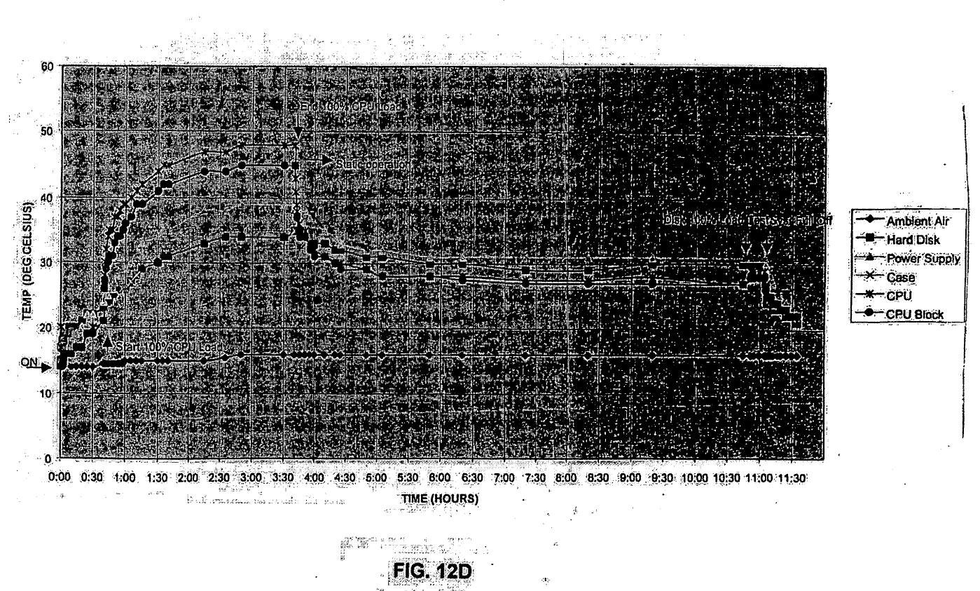

As shown in FIGS. 12A and 12D, temperatures at all monitored locations in the computer rise rapidly when the CPU is put under full (100%) load. Under these conditions, the CPU has the highest temperature for the measured locations and the “CPU block” or thermal connector is the next hottest of the locations. As shown in FIGS. 12C and 12D, temperatures at all monitored locations in the computer drop rapidly when the CPU load ends. Thereafter, as shown also in FIG. 12B, the power supply and disk drives have the highest temperatures for the measured locations.

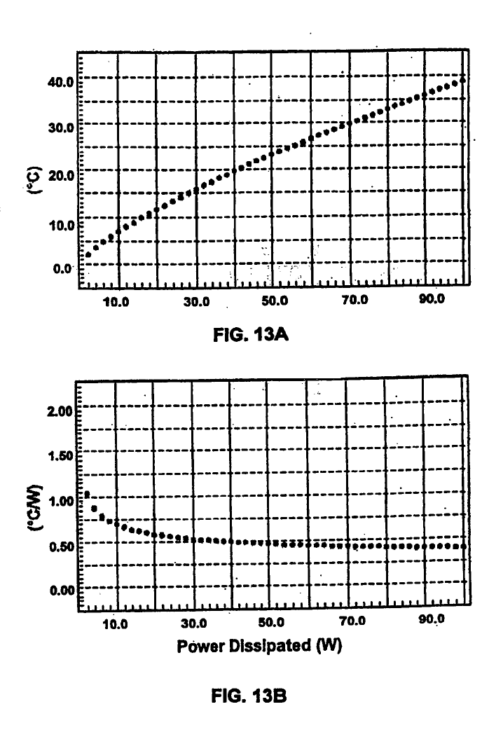

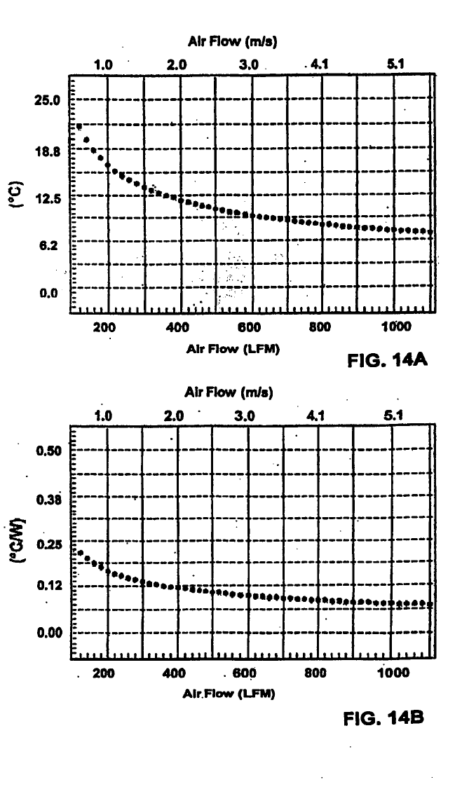

The relative effect of natural and forced convection on the temperature of the heat dissipation element is shown in FIGS. 13A-13D. With natural convention, the temperature of the heat dissipation element rises to almost 40° C. in 90 minutes, as shown in FIG. 13A, and the ratio of temperature to power falls to about 0.75, as shown in FIG. 13B. With forced convention, for the same system for removing heat, the temperature of the thermally conductive is reduced between 20° C. and 7° C., depending on the rate of air flow, as shown in FIG. 14A, and the ratio of temperature to power is reduced between 0.25 and 0.7, as shown in FIG. 14B.

A number of implementations of the invention have been described. Nevertheless, it will be understood that various modifications may be made without departing from the spirit and scope of the invention. For example, the invention can be implemented to remove heat from industrial computers, desktop boxes (e.g., cable boxes), computer storage systems (e.g., SAN and NAS), telecommunication switching equipment, laptop computers, wireless base stations, supercomputers, clusters of computing devices, and home network central hubs. The above described features for isolating elements from vibrations can be implemented for any elements of the encased electronic device. Moreover, these features can provide isolation from vibration caused by any sources of vibration, including sources external and sources internal to the encased electronic device. Accordingly, other implementations are within the scope of the following claims.

1. A system for removing heat, comprising
one or more conduction pathways, wherein at least a portion of one of the one or more conduction pathways is a flexible thermal connector;
a thermal ground, wherein the one or more conduction pathways thermally couple one or more heat-producing elements of an encased electronic device to the thermal ground so that the thermal ground receives heat produced by the heat-producing elements; and
a heat dissipation element, wherein the heat dissipation element is thermally coupled to the thermal ground and is configured to transfer heat from the thermal ground to an environment external to the encased electronic device, and wherein the conduction pathways, the thermal ground, and the heat dissipation element provide a capacity to remove heat from the encased electronic device such that heat removal by convection from the heat-producing elements is not required.

2. The system of claim 1, wherein:
the flexible thermal connector is a flexible, thermally conductive cable.

3. The system of claim 1, wherein:
the flexible thermal connector is made of pitch-based carbon fiber, diamond, vapor grown carbon fibers (VGCF), or carbon nanotubes.

4. The system of claim 1, wherein:
the flexible thermal connector includes filler material selected from the group consisting of silver, gold, copper, aluminum, graphite, carbon black, emerald, sapphire, beryllium oxide (BeO), boron nitride (BN), silicon carbide (SiC), and aluminum nitride (AlN).

5. The system of claim 1, wherein:
the flexible thermal connector is made of thermally conductive fibers coated with a more highly thermally conductive material.

6. The system of claim 2, wherein:
the flexible thermal connector has a protective layer that provides thermal insulation.

7. The system of claim 6, wherein:
the protective layer is made in whole or in part from polyvinylchloride (PVC), nylon, polyethylene, polypropylene, polyester, polyurethane foam, long density polyethylene (LDPE), closed cell foams, sponge rubber, natural cork, silica aerogel, Cab-O-Sil, mica, wood flour, zirconium dioxide, or silicon dioxide.

8. The system of claim 1, wherein:
the flexible thermal connector is secured to a thermal ground, a heat spreader, or a heat-producing device with a collar.

9. The system of claim 1, wherein:
the flexible thermal connector is thermally coupled to a thermal ground, a heat spreader, or a heat-producing device with a plating of a highly conductive material or a thermal pad.

10. The system of claim 1, wherein:
the flexible thermal connector is thermally coupled to a heat-producing device and is electrically insulated from the heat-producing device.

11. The system of claim 1, wherein:
the flexible thermal connector thermally couples one of the one or more heat-producing elements to the thermal ground so that the thermal ground receives heat produced by the heat-producing elements.

12. The system of claim 11, wherein:
the flexible thermal connector is coupled to one of the one or more heat-producing elements at a first area and is coupled to the thermal ground at a second area, where the first area is smaller than the second area.

13. The system of claim 1, wherein:
the heat dissipation element is made of fibers that are free-floating and moveable by convection.

14. The system of claim 1, wherein:
the electronic device includes a computer or a computer subsystem encased in a thermally conductive casing.

15. The system of claim 13, wherein:
the electronic device includes two or more computers or computer subsystems encased in a thermally conductive casing and separated by thermal spreaders.

16. The system of claim 13, wherein:
the electronic device is a portable laptop computer.

17. The system of claim 15, wherein:
the heat dissipation element is made of fibers that are free-floating and moveable by convection.

18. An apparatus for dissipating heat, comprising:
a bundle of thermally conductive and flexible fibers thermally coupled to a heat-producing device, at least some of the fibers being unsecured at one end and moveable by convection.

19. A system for removing heat, comprising:
one or more conduction pathways;
a thermal ground, wherein the one or more conduction pathways thermally couple one or more heat-producing elements of an encased electronic device to the thermal ground so that the thermal ground receives heat produced by the heat-producing elements; and
a heat dissipation element that is made of fibers that are free-floating and moveable by convection, wherein the heat dissipation element is thermally coupled to the thermal ground and is configured to transfer heat from the thermal ground to an environment external to the encased electronic device, and wherein the conduction pathways, the thermal ground, and the heat dissipation element provide a capacity to remove heat from the encased electronic device such that heat removal by convection from the heat-producing elements is not required.

20. The system of claim 18, wherein:
the electronic device is a computer encased in a thermally conductive casing; and
the heat-producing elements of the computer include any combination of a central processing unit, one or more PC cards, one or more disk drives, and one or more power supplies.
